(19) United States
(12) Patent Application Publication
(10) Pub. No.: US 2005/0176250 A1
(43) Pub. Date: Aug. 11, 2005

(54) Polishig fluid for metallic films and method for producing semiconductor substrate using the same

(76) Inventors: Hideaki Takahashi, Chigasaki (JP); Koshi Okita, Kawasaki (JP); Kuon Miyazaki, Yokohama (JP); Takayuki Matsuda, Kawasaki (JP)

Correspondence Address: BIRCH STEWART KOLASCH & BIRCH, PO BOX 747, FALLS CHURCH, VA, 22040-0747, US

(21) Appl. No.: 10/486,726

(22) PCT Filed: Aug. 8, 2002
(86) PCT No.: PCT/JP02/08135

(30) Foreign Application Priority Data
Aug. 16, 2001 (JP) 2001-246898
Nov. 27, 2001 (JP) 2001-361030

(51) Int. Cl. H01L 21/302

(52) U.S. Cl. 438/691

(57) ABSTRACT

A polishing fluid for metallic films, wherein the etching rate is 10 nm/min. or less, the polishing rate under a load of 10 KPa is 200 nm/min. or more, and the contrast, a ratio of the above-mentioned polishing rate to the etching rate, is 20 or more; and a method for producing a semiconductor substrate using the same.

### TECHNICAL FIELD

The present invention relates to a polishing fluid for metallic films used for polishing a metallic film formed on a semiconductor substrate, and to a method for producing a semiconductor substrate using said polishing fluid.

### BACKGROUND ART

Due to the rapid progress of the LSI technique, integrated circuits tend to be scaled down and employ more the structure of multilevel interconnection, from day to day. The introduction of multilevel interconnection integrated circuits is an important factor aggravating the unevenness of the semiconductor surface which, together with the scale down of integrated circuits, promotes disconnection, reduction of electric capacity and occurrence of electromigration and results in the reduction of yield and reliability of the product.

Thus, a variety of processing techniques have hitherto been developed for making flat the metallic wirings and interlayer dielectric in the multilevel interconnection substrates. One of such techniques is the CMP (chemical mechanical polishing) technique. The CMP technique is necessary for the flattening of interlayer dielectrics, formation of buried distribution wires, formation of plugs, etc. in the production of semiconductors.

CMP is carried out by rotating a carrier and a polishing pad respectively while pushing a flat wafer usually made of a semiconductor material, set on the carrier against the wet polishing pad under a constant pressure. At this time, a polishing fluid introduced between the wafer and the polishing pad progresses the polishing of wirings and convexities of dielectrics mainly by way of the mechanical polishing action, accompanied by some chemical action to achieve the desired flattening.

There have hitherto been made a number of proposals using various polishing fluids and polishing methods for polishing metallic film in semiconductor substrates. As in Toshiro Doi, et al.: “CMP Technique in the Flattening of Semiconductors” Page 235, July 1998, published by Kogyo Chosakai, in the CMP of a metallic film, an oxidant present in a polishing fluid chemically oxidizes the surface of the metallic film and converts it into a passive state and lowers the pH value to be in the acidic region to cause slight corrosion of the metal (etching). Under such a condition, mechanical polishing is carried out by a polishing pad and abrasive grains. For instance, as polishing fluids for metallic films composed of aluminum or the like formed on a semiconductor substrate, polishing fluid obtained by dispersing aluminum oxide as abrasive grains in an aqueous solution of nitric acid having a pH value of 3 or less (U.S. Pat. No. 4,702,792), polishing fluid obtained by mixing abrasive grains composed of aluminum oxide or silicon dioxide with an acidic aqueous solution of sulfuric acid, nitric acid, acetic acid or the like (U.S. Pat. No. 4,944,836), etc. can be referred to. Among such polishing fluids, polishing fluids prepared by using aluminum oxide or silicon dioxide as abrasive grains and dispersing the abrasive grains in a solution of oxidant such as hydrogen peroxide and the like, such as the one obtained by dispersing aluminum oxide in an aqueous solution of hydrogen peroxide and phosphoric acid (U.S. Pat. No. 5,209,816) are usually and widely used. When aluminum oxide is used as an abrasive grain for flattening a metallic film on a semiconductor substrate, however, the α-form of aluminum oxide is disadvantageous in that defects such as microscratches, orange peel and the like may appear on the surface of a metallic film or dielectric, even though it shows a high polishing rate. On the other hand, when the γ-form of aluminum oxide, amorphous alumina or silicon dioxide is used as the abrasive grains, a sufficient polishing rate cannot be achieved upon polishing a metallic film even though the appearance of defects such as microscratches and orange peel on the surface of a metallic film or dielectric can be suppressed. As above, polishing fluids prepared by dispersing abrasive grains composed of a metallic oxide such as aluminum oxide, silicon dioxide or the like in an aqueous solution have a problem of surface scratches caused by the low dispersibility of the abrasive grain itself. In addition to the above, there are various practical problems, such as dishing (a phenomenon that the central part of a metallic film is excessively polished as compared with the peripheral part as seen in 4 of FIG. 1D) and the generation of defects such as pits, voids or the like, etc., due to an excessive progress of wet etching, in the cases where a liquid oxidant, such as hydrogen peroxide, or a metallic etchant, such as ammonium persulfate or the like is used (JP-A-6-313164).

With the aim of overcoming these disadvantages, methods in which a chemical reagent capable of forming a protective film on the surface of metallic film, such as an anticorrosive agent, chelating agent or the like, is added to the polishing fluid have been proposed (JP-A-8-83780, JP-A-11-195628). However, although such chelating agent can suppress the etching and prevent the occurrence of dishing, etc., it causes a problem that a protective film is formed even in the area to be polished to thereby extremely lower the polishing rate. Although it has been attempted to optimize the amount of etching agent or chelating agent in order to overcome the above-mentioned problem, it is difficult to find out the conditions under which both of the requirements, high polishing rate and less etching and dishing, are met. In addition to this problem, there was also a problem that the results of processes are not reproducible as the results are apt to be influenced by other process conditions. Further, there has been an attempt to obtain a polishing rate of 200 nm/min. or more by mechanically removing the above-mentioned protecting film under a high polishing pressure of 20 KPa or more (JP-A-2000-252242). However, in the case of porous type low-dielectric constant type insulating films, which will be widely used hereafter, due to their low film strength and low adhesiveness to a substrate, an excessive stress to a substrate causes the peeling and breakage of insulating film. Further, when mechanical polishing with a pad is carried out under an enhanced polishing pressure, the influence of the pad surface becomes greater upon polishing, so that the control of the state of the pad surface by conventional dressing becomes difficult, and thus the process control becomes more difficult. Further, such a technique accelerates the consumption of costly pads to increase the process cost.

Now, polyoxo acids, particularly heteropoly acid, have high acidity and oxidizing activity, as mentioned in “Chemistry of Poly Acids” (edited by Japanese Chemical Society, published by Gakkai Shuppan Center, August 1993), and the use of these substances in the treatment for making a metal into a passive state or an etching treatment of a metal is described in JP-A-9-505111, etc. An example of actual use of a heteropoly acid as an etching agent for a semiconductor surface (Applied Surface Science, Vol. 135, No. 1/4, pp. 65-70 (1998, 10.8) and an attempt to use a polyoxo acid or its salt as an etching agent for polishing (JP-A-2000-119639) have been disclosed.

Especially in the latter paper, there are described two embodiments, namely an embodiment of using only polyoxo acid or its salt as an etching agent for polishing (i.e. the first polishing fluid composition) and an embodiment of adding thereto known abrasive grains (i.e. the second polishing fluid composition). In the case of the first polishing fluid composition, if a heteropoly acid is used alone as an etching agent for polishing metallic films, it acts as a liquid oxidant as it is soluble in water. Therefore, both of the above-mentioned two requirements, i.e. polishing rate and dishing-suppressing performance, cannot be satisfied simultaneously. In other words, if the concentration of heteropoly acid is increased in order to improve the polishing rate, etching is simultaneously promoted to cause dishing. On the other hand, if a basic substance such as ammonia is added to the heteropoly acid and the resulting heteropoly acid salt is used, even though the etching may be suppressed, the polishing rate simultaneously decreases and the polishing does not progress efficiently. Thus, it has been proposed to mix abrasive particles into the first polishing fluid composition to prepare a second polishing fluid composition for the purpose of enhancing the polishing rate. However, this provides nothing more than mechanical polishing by the use of abrasive particles, wherein a high polishing load is necessary to achieve a high polishing rate. Accordingly, such a technique does not meet the object of the present invention which is to achieve a high polishing rate under a low load.

Beside the above, a technique of dispersing abrasive grains in a fluid containing heteropoly acid to prepare an aqueous dispersion for chemical-mechanical polishing has also been proposed (EP-A-1123956). However, also in this case, actually, a high polishing load of about 30 KPa has to be applied, for achieving a high polishing rate of 300 nm/min., while suppressing the etching property causing the dishing.

### DISCLOSURE OF THE INVENTION

The object of the present invention is to provide a polishing fluid used for polishing a metallic film formed on a semiconductor substrate, characterized by:
being able to polish a metallic film on a semiconductor substrate at a high polishing rate even under a low load;
being able to control the etching property causing the dishing to a low level;
being able to suppress the occurrence of defects in the polished surface, such as scratches, erosion (a phenomenon that the insulating film 2 existing in the peripheral area of metallic film 4 as in FIG. 1D is polished), etc., as it substantially does not contain abrasive grains necessary for mechanical polishing; and
further requiring no complicated step of dressing;
as well as a method for producing a semiconductor substrate using said polishing fluid.

The present inventors have conducted extensive studies with the aim of solving the above-mentioned problems. As a result, it has been found that, if polishing is carried out by the use of a specific polishing fluid for metallic films, the suppression of etching and the high polishing rate under a low load can be achieved simultaneously, which has hitherto been impossible, and that such a polishing method is effectively applicable also to the metallic films on a fragile porous type low dielectric constant insulating film substrate. Based on these findings, the present invention has been accomplished. Thus, the aspects of the present invention are as mentioned below.

(1) A polishing fluid for metallic films, the polishing fluid having an etching rate of 10 nm/min. or less, a polishing rate under a load of 10 KPa of 200 nm/min. or more, and a contrast ratio of the polishing rate to the etching rate of 20 or more.

(2) A polishing fluid for metallic films, comprising a polyoxo acid and/or a salt thereof, a water-soluble polymer and/or a non-ionic surfactant, and water.

(3) A polishing fluid for metallic films according to (2), comprising a particulate composite material consisting of a polyoxo acid and/or a salt thereof and a non-ionic surfactant.

(4) A polishing fluid for metallic films according to any one of (2) to (3), wherein abrasive grains are substantially not contained.

(5) A polishing fluid for metallic films according to any one of (2) to (4), wherein said polyoxo acid and/or a salt thereof is a heteropoly acid and/or a salt thereof.

(6) A polishing fluid for metallic films according to any one of (2) to (5), wherein the HLB of the non-ionic surfactant is 5 to 12.

(7) A polishing fluid for metallic films according to any one of (2) to (6), wherein the non-ionic surfactant is a polyoxyethylene ether of a saturated type higher alcohol having 8 to 24 carbon atoms.

(8) A polishing fluid for metallic films according to any one of (2) to (7), wherein the non-ionic surfactant is a combination of two or more kinds of non-ionic surfactants with different HLBs.

(9) A method for producing a semiconductor substrate comprising a step of polishing a metallic film formed on the semiconductor substrate, wherein the polishing is carried out with a polishing fluid for metallic films according to (1) or (2) under a load of 15 KPa or less.

(10) A method for producing a semiconductor substrate comprising a step of polishing a metallic film formed on the semiconductor substrate with a polishing stool, wherein the polishing is carried out with a polishing fluid for metallic films according to (1) or (2) at a relative velocity between the semiconductor substrate and the polishing stool of 40 m/min. or more.

(11) A method according to (9) or (10), wherein, in the step of polishing, the polishing is carried out with a polishing pad not subjected to a dressing treatment.

(12) A method according to any one of (9) to (11), wherein, in the step of polishing, the polishing is carried out with a polishing pad having an average surface roughness (Ra) of 1,000 nm or less on its surface.

(13) A method according to (9) or (10), wherein, in the step of polishing, the polishing is carried out with a polishing fluid for metallic films according to (1) or (2) and by a polishing pad containing an inorganic filler.

(14) A method according to any one of (9) to (13), wherein the relative dielectric constant (K) of the insulating film constituting the semiconductor substrate is 2.5 or less.

(15) A polishing fluid for metallic films according to (1), wherein abrasive grains are substantially not contained.

### BRIEF DESCRIPTION OF THE DRAWINGS

FIGS. 1A to 1D are outlined cross-sectional views illustrating examples of the formation of metallic wirings using the CMP technique.

Hereinbelow, the present invention will be explained more concretely.

As used in the present invention, the term “etching rate” means the thickness of a metallic film which disappears over a certain period of time, when a substrate with a metallic film formed thereon is immersed in a vigorously stirred polishing fluid. Specifically, a container having an inner diameter of 5 cm is filled with 80 ml of a polishing fluid, and the polishing fluid is stirred at 25,000 rpm by means of Homogenizer ULTRA-TURRAX T8 manufactured by IKA-WERKE Co. (with shaft S8N-8G). A substrate of Si wafer (15 mm square) having a metallic film formed thereon is immersed in the polishing fluid under stirring for 3 minutes. From the difference in the thicknesses of the metallic film before and after the immersion, the thickness of the metallic film having disappeared per unit period of time is calculated.

As used in the present invention, the term “polishing rate” means the thickness of metallic film which disappears over a certain period of time, when a semiconductor substrate is polished by a general-purpose polishing apparatus for a semiconductor substrate under predetermined conditions. Specifically, polishing of a substrate (4″ silicon wafer having a Cu film with a thickness of 1 μm) is carried out by using Polishing Apparatus MA-300D manufactured by Musashino Denshi Co. (stool diameter 300 nm), and using IC-1400 Rodel Nitta Co. (made of foamed polyurethane) as a polishing pad, under a predetermined load, while feeding the polishing fluid at a rate of 50 ml/min., under a condition that the relative velocity between the substrate and the polishing stool is 50 m/min. From the thicknesses of Cu film before and after the polishing, the thickness of the metallic film having disappeared per unit period of time is calculated.

The present inventors have found that, when a polishing fluid having the above-standardized properties in specific ranges is used, it is possible to polish the metallic film on a semiconductor with excellent properties, such as: that polishing can be carried out under a low load at a high rate; that the occurrence of defects on the polished surface such as scratches, dishing, erosion, etc. can be suppressed; that the process control, such as control of the surface state of the polishing pad, can be simplified; and that the cost of the process can be lowered by reducing the consumption of pads, etc.

First of all, if a polishing fluid having an etching rate of 10 nm/min. or less is used, corrosion of a metal surface can be controlled, so that the metal surface is not much roughened at the time of polishing, and no great dishing occurs when a substrate having a pattern is polished.

Next, if a polishing rate under a load of 10 KPa is 200 nm/min. or more and a contrast, i.e. the ratio of the polishing rate/etching rate, is 20 or more in a polishing fluid for metallic films, it is possible to fulfil both the improvement of polishing performance, such as prevention of dishing, and the shortening of polishing time simultaneously, both of which are problems to be solved in a CMP process under a condition of low load.

As polishing fluids having the performance standardized in the present invention, polishing fluids comprising polyoxo acid and/or a salt thereof, a water-soluble polymer and/or a nonionic surfactant, and water can be referred to. The polishing fluids of the present invention may contain other ingredients, such as usually employed abrasive grains, oxidants and the like, so far as their presence does not disturb the effect of the present invention or the desired purpose, as will be mentioned later. However, the object of the present invention can be fundamentally achieved by the above-mentioned ingredients only. Especially, the polishing fluid of the present invention is characterized in that it substantially does not contain abrasive grains which have been used in the conventional polishing fluids.

The polyoxo acids used in the present invention are the products of the condensation of an oxygen acid containing Mo, V, W, Ti, Nb, Ta or the like as a constitutional element. Isopoly acid and heteropoly acid belong to said polyoxo acid.

“Isopoly acid” means a condensed oxygen acid containing at least one of the above-mentioned constitutional elements of polyoxo acids and includes polymolybdic acid, polyvanadic acid, polytungstic acid, polytitanic acid, polyniobic acid, polytantalic acid, etc. Among these acids, preferably usable in the present invention for the purpose of polishing a metal are polymolybdic acid, polyvanadic acid and polytungstic acid from the viewpoint of the ability of etching (oxidizing or dissolving) the metal.

“Heteropoly acids” are acids obtained by incorporating a hetero element into the above-mentioned isopoly acids as a central element, and are constituted from a condensed co-ordinated element, a central element and oxygen. Herein, the “condensed co-ordinated element” means the constitutional element of the above-mentioned polyoxo acids. As preferable examples thereof, at least one member selected from the group consisting of Mo, W and V can be referred to. In addition to them, Nb, Ta and the like may also be included in the preferable elements. The central element of the heteropoly acid is at least one element selected from the group consisting of P, Si, As, Ge, Ti, Ce, Mn, Ni, Te, I, Co, Cr, Fe, Ga, B, V, Pt, Be and Zn. The atomic ratio between the condensed co-ordinated element and the central element (condensed co-ordinated element/central element) is 2.5 to 12.

As concrete examples of the above-mentioned heteropoly acid, phosphomolybdic acid, silicomolybdic acid, phosphovanadomolybdic acid, silicovanadomolybdic acid, phosphotungstomolybdic acid, silicotungstomolybic acid, phosphovanadotungstomolybdic acid, silicovanadotungstomolybdic acid, phosphovanadotungstic acid, silicovanadotungstic acid, phosphomolyboniobic acid, boromolybdic acid, borotungstomolybdic acid, borovanadomolybdic acid, borovanadotungstic acid, cobaltomolybdic acid, cobaltovanadotungstic acid, phosphotungstic acid, silicotungstic acid, phosphovanadic acid, silicovanadic acid, and the like can be referred to, although these acids are not limitative.

Among the above-mentioned polyoxo acids, preferable are heteropoly acids from the viewpoint of acid strength and oxidizing power sufficient to etch a metal as used for the purpose of polishing; and further preferable are phosphomolybdic acid, silicomolybdic acid, and vanadium-introduced products thereof such as phosphovanadomolybdic acid, silicovanadomolybdic acid, and the like. The polyoxo acids may be used alone or in the form of a mixture thereof. It is also possible to use these polyoxo acids in the form of polyoxo acid salts prepared by adding a basic substance to the polyoxo acids, for the purpose of adjusting the acidity of the resulting polishing fluid composition to control the polishing performance thereof. As the polyoxo acid salt, salts formed between the polyoxo acid and a metal, ammonium or an organic amine can be referred to.

Although the content of polyoxo acid and/or salt thereof in the polishing fluid of the present invention is not particularly limited, it is preferably 0.1-30% by weight and further preferably 0.5-15% by weight. If the content of polyoxo acid or salt thereof is lower than the above-mentioned range, it may be difficult to exhibit a sufficient polishing rate. When said content exceeds the above-mentioned range, there can be observed no conspicuous improvement in polishing performance brought about by the increment.

The water-soluble polymer used in the present invention includes, but is not limited to, ethers such as polyethylene glycol, polypropylene glycol, polyethylene glycol alkyl ether and the like; vinyl polymers such as polyvinyl alcohols, polyvinyl pyrrolidone, polyacrolein and the like; polycarboxylic acids and salts thereof such as polyacrylic acid, polymethacrylic acid, polyacrylamide, polyamic acid, ammonium salts of polyacrylic acid, and the like; polysaccharides such as methyl cellulose, hydroxypropyl cellulose, carboxymethyl cellulose, cellulose acetate, cellulose nitrate, cellulose sulfate, pectin and the like; and gelatin, starch, albumin etc.

It has been reported that these water-soluble polymers are incorporated into a polishing fluid composition as a thickener (JP-A-8-302338) or as a surfactant (JP-A-2000-252242). However, the object of using the water-soluble polymer in the present invention is different from those of this prior art. Thus, in the present invention, a water-soluble polymer is used in combination with the polyoxo acid, by which the progress of etching can be suppressed and the occurrence of dishing can be controlled while maintaining a high polishing rate even under a low load. Among the water-soluble polymers mentioned above, polyethylene oxide, polyvinylpyrrolidone, polyvinyl alcohol and cellulose derivatives are preferable from the viewpoint of polishing performances, such as the suppression of etching and the improvement of polishing rate under a low load, or from the viewpoint of the dispersibility of the formed particles.

As to the water-soluble polymer to be added, not only the species thereof but also the molecular weight thereof markedly affect the performance of the polishing fluid. Although there is a general tendency that a higher molecular weight of the water-soluble polymer to be added gives a higher effect of suppressing the etching, the actual results are quite diverse because the dispersibility of particles and polishing rate are also related, depending on the kind of water-soluble polymer.

The content of the water-soluble polymer in the polishing fluid of the present invention is not particularly limited, but varies depending on the kind of the polymer and the kind and quantity of polyoxo acid or salt thereof. Preferably, however, it is in the range of 0.01-50% by weight and more preferably 0.05-30% by weight. If its amount is smaller than the above-mentioned range, sufficient etching-suppressing effect cannot be achieved, and it may be difficult to control the occurrence of dishing. If its amount exceeds the above-mentioned range, the polishing fluid becomes difficult to handle, because of a rise in viscosity, for example.

When used in combination with the above-mentioned polyoxo acid, the non-ionic surfactant of the present invention makes it possible to suppress the progress of etching while maintaining a high polishing rate under a low load and thereby suppressing the occurrence of dishing. Surprisingly, this effect is not found when an ionic surfactant such as an anionic or cationic surfactant is used, but is found especially remarkably when a non-ionic surfactant, especially a non-ionic surfactant having an HLB of 5-12 is used. As referred to herein, the term “HLB” (Hydrophile-Lipophile Balance) is a parameter indicating the hydrophilic character of a surfactant. In the case of the non-ionic surfactants used in the present invention, this value is in the range of from 0 to 20. A higher value of HLB means a higher hydrophilic character.

As said non-ionic surfactant, the polyethylene glycol type and polyhydric alcohol type non-ionic surfactants described in “Shin Kaimenkasseizai Nyuumon (Introduction to the New Surfactants)” Takehiko Fujimoto, Nov. 1, 1960, published by Sanyo Kasei Kogyo K. K., page 92, Tables 2.5.1, can be used. The polyethylene glycol type non-ionic surfactants are those prepared by adding ethylene oxide to various hydrophobic groups to introduce a hydrophilic group into the molecule, and examples thereof include higher alcohol ethylene oxide adducts, alkylphenol ethylene oxide adducts, fatty acid ethylene oxide adducts, polyhydric alcohol fatty acid ester ethylene oxide adducts, higher alkylamine ethylene oxide adducts, fatty acid amide ethylene oxide adducts, fatty oil ethylene oxide adducts, polypropylene glycol ethylene oxide adducts, and the like. On the other hand, the polyhydric alcohol type non-ionic surfactants are those prepared by bonding a hydrophilic polyhydric alcohol to a hydrophobic fatty acid via an ester group or an amide group. Examples thereof include glycerol fatty acid esters, pentaerythritol fatty acid esters, sorbitol fatty acid esters, sorbitan fatty acid esters, sucrose fatty acid esters, alkanolamine fatty acid amides, and the like.

Among the above-mentioned non-ionic surfactants, those having an HLB value of 5 to 12 are preferably used in the present invention. If the HLB is smaller than 5, the polishing particles formed have too strong hydrophobicity, which may result in the precipitation of the particles or a phase separation due to low dispersibility. On the other hand, if the HLB is greater than 12, the polishing particles have too high hydrophilicity, which may make it difficult to form the particles and to exhibit the etching-suppressing effect.

The non-ionic surfactants of the present invention are preferably those classified as said polyethylene glycol type surfactants. As examples thereof, polyoxyethylene ethers of higher alcohols having 8-24 carbon atoms, polyoxyethylene ethers of alkylphenols, and polyoxyethylene ethers of polypropylene glycol (PLURONIC type) can be referred to, among which polyoxyethylene ethers of higher alcohols having 8-24 carbon atoms are especially preferable. The polyoxyethylene ethers of higher alcohols having 8-24 carbon atoms can be divided into an unsaturated type having a carbon-carbon double bond such as an oleyl group in the molecule thereof and a saturated type having no carbon-carbon double bond at all. Because a saturated group does not undergo oxidative deterioration and shows no change in performance over time, polyoxyethylene ethers of saturated type higher alcohols are preferable. Examples thereof include polyoxyethylene decyl ether, polyoxyethylene lauryl ether, polyoxyethylene cetyl ether, polyoxyethylene stearyl ether, polyoxyethylene 2-ethylhexyl ether, polyoxyethylene tridecyl ether, polyoxyethylene isostearyl ether, polyoxyethylene synthetic alcohol ether (said synthetic alcohol has 12-15 carbon atoms), and the like.

These non-ionic surfactants may be used alone. However, if two or more kinds of the surfactants different from one another in HLB are used in combination, the excellent properties of the polishing fluid of the present invention, namely high dispersibility and low etching property of the formed polishing particles, high polishing rate property under a low load, etc. can be exhibited easily. Furthermore, when two or more kinds of non-ionic surfactants different from one another in HLB are used in combination, it is possible to mix together the surfactants previously and thereafter mix them with polyoxo acid (or salt thereof) or mix the surfactants simultaneously with polyoxo acid (or salt thereof). Preferably, however, a surfactant having a higher HLB is firstly mixed with polyoxo acid (or salt thereof) and thereafter the surfactant having a lower HLB is mixed thereinto. Such a procedure is advantageous in that a low etching property and high polishing rate property under a low load can be exhibited while maintaining a high dispersibility of the formed polishing particles.

In the polishing fluid of the present invention, the content of the non-ionic surfactant is not particularly limited. Although it may vary depending on the kind of the surfactant used and the kind and amount of the polyoxo acid (or salt thereof), the content of the surfactant is usually 0.1-50% by weight and preferably 0.5-25% by weight. If its content is smaller than the above-mentioned range, sufficient etching-suppressing effect cannot be exhibited and occurrence of dishing cannot be controlled. If its content is higher than the above-mentioned range, deterioration in the handling property of the product, such as a rise in viscosity, can occur.

The polishing fluid of the present invention is characterized by comprising a water-soluble polymer and/or a non-ionic surfactant. In order to achieve a high polishing rate, however, the use of a non-ionic surfactant is preferable.

In the polishing fluid of the present invention, water is usually used as a medium. The dissolution or dispersion of the polyoxo acid (or salt thereof) and the water-soluble polymer and/or the nonionic surfactant is usually carried out by stirring. A process wherein a sufficient dispersion is carried out by the use of a homogenizer, ultrasonic waves, a wet type medium mill, or the like is preferably employed.

Preferably, the thus-prepared polishing fluid is in a highly dispersed state in water, of a composite material (micelle particles) in which polyoxo acid (or a salt thereof) is incorporated into micelles formed from a water-soluble polymer and/or a non-ionic surfactant due to an interaction between the polyoxo acid (or a salt thereof) and the water-soluble polymer and/or non-ionic surfactant. The case where a non-ionic surfactant is used is especially preferable because the existence of the non-ionic surfactant facilitates the formation of the composite material. The “composite material” referred to herein fundamentally can be subjected to a particle size measurement by the wet type particle size analyzer and observation of the above structure by means of a transmission type electron microscope. It preferably has a number average particle size in the range of about 10 nm to 1 μm as determined by means of a wet type particle size analyzer. Although composite materials having a number average particle size of smaller than about 10 nm or composite materials which are so fine that their particle size cannot be measured and exist in a highly dispersed state are also included in the scope of the present invention, such composite materials are disadvantageous because they generally give a highly viscous composition. Thus, if workability at the time of polishing is taken into consideration, composite material particles, the particle size of which is measurable and the structure of which is observable as mentioned above are preferable.

Although the details of the mechanism of polishing with the polishing fluid of the present invention are not clearly known, it is considered that the micelle particles formed through the interaction between polyoxo acid (or salt thereof) and water-soluble polymer and/or non-ionic surfactant act as polishing particles exhibiting a chemical polishing action, and can exhibit a high polishing rate even under a low load while maintaining a low etching rate and suppressing the occurrence of dishing. As noted above, the polishing particle of the present invention is a micelle-form particle, which is essentially different in nature from the abrasive grain used for the purpose of mechanical polishing. Accordingly, in the present invention, the problems in the conventional mechanical polishing, such as scratches due to coagulated abrasive grains, the damage to the underlying substrate due to the load at the time of polishing, etc. can be eliminated.

In the polishing fluid of the present invention, it is also possible to use abrasive grains for the purpose of additionally enhancing the polishing rate and giving some factors of mechanical polishing, so far as the above-mentioned problems such as scratching, etc. do not occur. However, it is a characteristic feature of the present invention that the polishing fluid substantially does not contain abrasive grains. When an abrasive grain is used, its content is preferably less than 1% by weight. Examples of the abrasive grain used herein include inorganic particles such as silicon dioxide, titanium oxide, cerium oxide, aluminum oxide, zirconium oxide, magnesium oxide and the like; organic fine particles such as styrene copolymers, acrylic copolymers, polyvinyl chloride, polyacetal, saturated polyester, polyamide, polyimide, polycarbonate, phenoxy resin, polyolefin, olefin copolymers and the like; and organic particles such as amorphous carbon, carbon black and the like. Abrasive grains usually used for the purpose of mechanical polishing are inorganic particles having high hardness.

Since the polishing fluid of the present invention is very low in the property of etching a metallic film, namely the property which causes dishing, it is usually unnecessary to use a protecting film-forming agent with the polishing fluid. However, it is also possible to add a compound that forms a chelate or a complex with a metallic film to further suppress the etching, if necessary, as long as the addition of such a compound does not lower the polishing rate substantially. Especially when the metal is copper or a copper alloy consisting mainly of copper, the addition of benzotriazole or quinaldic acid as a chelating agent is effective. As an anti-corrosive agent, in addition to the above, benzotriazole derivatives such as tolyltriazole, benzotriazolecarboxylic acid and the like, cystine, haloacetic acid, glucose, dodecylmercaptan and the like can be referred to. As to the amount of the anti-corrosive agents used in the present invention, an amount of 100 ppm or less and preferably 50 ppm or less is sufficient for the purpose, which is much smaller than the amount of anti-corrosive agent added to the conventional abrasive grains. Inversely, addition of the anti-corrosive agent in too large of an amount is undesirable, because it causes a decrease in the polishing rate and makes it impossible to achieve the desired polishing performance.

Into the polishing fluid of the present invention, a known oxidant may be incorporated for the purpose of improving the polishing rate of metallic film, as long as its addition does not cause excessive etching. As the oxidants which can be incorporated, known oxidants can be referred to, the examples of which include peroxides such as hydrogen peroxide and the like, perchloric acid, perchloric acid salts, periodic acid, periodic acid salts, persulfuric acid, persulfuric acid salts, nitric acid salts, etc.

According to the need, an acid may be incorporated into the polishing fluid of the present invention. The polishing performance of metallic film can be controlled by varying the kind of acid to be added and the pH value of the resulting slurry. As the acid to be incorporated, known inorganic acids such as sulfuric acid, phosphoric acid, nitric acid and the like and known organic acids such as oxalic acid, citric acid, malic acid, acetic acid and the like can be referred to.

According to the need, a water-soluble alcohol such as methanol, ethanol, n-propanol, isopropanol, ethylene glycol, glycerin and the like may be added to the polishing fluid of the present invention.

The polishing fluid prepared in the above-mentioned manner is applied for the polishing and flattening of a metallic film formed on a semiconductor substrate. The metallic films on semiconductor substrate to be polished include metallic films for known wirings, plugs, contact metal layers and barrier metal layers, and the metallic film is composed of a metal selected from the group consisting of aluminum, copper, tungsten, titanium, tantalum, aluminum alloys, copper alloys, titanium nitride, tantalum nitride and the like. Among the above-mentioned metals, the present invention is suitably applied to metallic films composed of copper or copper alloys which have low surface hardness and thus are apt to form defects such as scratches, dishing, etc. It is also possible, however, to apply the present invention to the polishing of barrier metals composed of tantalum or the like.

Upon carrying out the polishing by the use of the polishing fluid of the present invention, a polishing method having a special characteristic feature is employed for fully exhibiting the performance of the polishing fluid. The present invention also relates to a method for producing a semiconductor substrate comprising such a polishing step.

The load in the polishing is extremely low, i.e. 15 KPa or less, preferably 10 KPa or less, and more preferably 5 KPa or less. This is for the reason that, since the polishing fluid of the present invention can give a high polishing rate under such a low load, it is unnecessary to carry out the polishing under a high load as in the conventional polishing. As a result, polishing can be carried out without applying an excessive stress to the substrate, which makes it possible to avoid the problem of peeling of metallic film due to the breakage of insulating film even in the manufacture of semiconductors with a porous type low dielectric constant insulating film, which is expected to be introduced and become the main innovation in the near future. Further, when the load during polishing is low, the influence of the pad surface on polishing is less, which facilitates the troublesome procedure of controlling the pad surface. Further, since the consumption of pads can be lessened, the process cost can be lowered. Therefore, as noted above, a variety of effects can be expected.

During polishing, the relative velocity between the semiconductor substrate and the polishing stool is preferably a high value of 40 m/min. or more. That is, even in the case where the factor of mechanical polishing is low as in the present invention, a higher polishing rate can be achieved and thereby the polishing time can be shortened by the contact between the polishing fluid and substrate at a high velocity.

The polishing fluid for metallic film according to the present invention has another characteristic feature in that it makes the dressing treatment of a polishing pad, which has been essential in the prior art, unnecessary. As referred to herein, the term “dressing treatment” means a step initially carried out on a polishing pad in the unused state and/or a step of refreshing the surface of used polishing pads. As to the dressing in the former meaning, slight dressing is often necessary because the existence of foreign material or burrs on the surface of the pad may cause scratch-formation at the time of polishing. However, when the polishing fluid of the present invention is used, the dressing in the latter meaning is unnecessary. That is, in the case of using a conventional polishing fluid containing the usual abrasive grains, the pad surface is finely fluffed by using a disc or a ring-form conditioner into the surface of which minute diamonds or the like are embedded, so that the abrasive grains in the slurry are held among the fluffs and a desired polishing rate is exhibited. Accordingly, a periodic control of the fluffing state of the pad surface is necessary for avoiding the deterioration of polishing performance. Further, the conventional polishing pad has a foamed structure for the sake of enhancing the holding property of abrasive grains in the slurry. With the progress of polishing, abrasive grains are taken into the pores to prevent the substitution with fresh abrasive grains to cause a gradual decrease in polishing rate. For the purpose of preventing this phenomenon, dressing is carried out with the aim of refreshing the surface of the pad. In the case of the present invention, contrariwise, substantially no abrasive grains are contained in the polishing fluid, so that no periodic dressing for the purpose of refreshing is necessary. This makes it unnecessary to carry out the troublesome step of dressing, and thereby the production process can be simplified and at the same time the consumption of costly pads can be suppressed and the process cost can be reduced.

In the method of the present invention, it is recommended to carry out the polishing with a flat pad having an average surface roughness (Ra) of 1,000 nm or less. According to the prior art, as has been mentioned above, the surface of the polishing pad is intentionally roughened by the procedure of dressing in order to achieve a desired polishing rate. However, if polishing is carried out with a pad low in surface flatness and smoothness, the unevenness on the surface promotes the occurrence of dishing and makes it impossible to carry out precise polishing. In the case of the present invention, contrariwise, the desired polishing rate can be obtained even when polishing is carried out with a pad of very high flatness (Ra is 1,000 nm or less). Accordingly, a precise polishing can be carried out without reducing the polishing rate.

According to the present invention, it is also possible to carry out polishing by the use of a pad containing an inorganic filler. Usually, a product prepared by foaming an organic polymer, such as polyurethane and the like, is used as a polishing pad. When a metallic film containing tantalum or a tantalum-containing compound, which are difficult to polish, is to be polished, by the use of the inorganic filler-containing pad, a mechanical factor of polishing is added and the polishing can be carried out with high efficiency. An inorganic filler-containing pad can be obtained by adding and dispersing a variety of inorganic fillers into a resin, such as polyurethane or the like, and thereafter forming the mixture into the form of a polishing pad. Specifically, the constituents of a urethane resin, namely an alcohol component such as a diol, polyol or the like and an isocyanate group-containing compound having a functionality of 2 or more are mixed together and reacted to form a urethane resin. Subsequently, an inorganic filler is added to the thus-obtained resin and kneaded to disperse the inorganic filler uniformly. After forming the uniform mixture thus-obtained into a polishing pad, a crosslinking reaction is carried out by a method of heat treatment or the like to obtain an inorganic filler-containing pad. As the inorganic fillers which can be used in the present invention, those conventionally used as abrasive grains, as have been mentioned above, can be referred to. Examples thereof include at least one member selected from silicon dioxide, titanium oxide, cerium oxide, aluminum oxide, zirconium oxide, chromium oxide, iron oxide, tin oxide, zinc oxide, composite metal oxides, metal hydroxides, silicon nitride and titanium nitride. When these inorganic fillers are added to a pad resin, the surface of the inorganic fillers may be coated with an organic silicon compound, such as a silane coupling agent or the like, in order to improve the dispersed state and the affinity at the resin/inorganic filler interface. As the inorganic filler, those having a particle diameter of 1 nm to 10 μm can be used, and those having a particle diameter of 10 nm to 5 μm are particularly preferable. When the particle diameter is smaller than 1 nm, it is difficult to achieve a sufficient polishing rate. If the particle diameter is larger than 10 μm, defects, such as scratching and the like, are apt to appear at the time of polishing to give an undesirable result. The amount of the inorganic filler in the constitutional resin is 0.1% by volume to 10% by volume, and preferably 1% by volume to 5% by volume. If the amount of the inorganic filler is too small, the addition of the inorganic filler does not exhibit sufficient effect. If the amount thereof is too large, problems arise in the formation of the pad, or the hardness becomes too high to cause defects, such as scratching and the like, at the time of polishing. As such inorganic filler-containing polishing pad, those that are prepared by adding cerium oxide to an urethane resin, such as MHC series manufactured by RODEL NITTA Co., can be used in the present invention.

The present invention is particularly effectively applicable to the cases where low dielectric constant insulating film in which the insulating film constituting a semiconductor substrate has a dielectric constant (K) of 2.5 or less is used, and particularly the case where porous type low dielectric constant insulating films which are mechanically fragile are used. That is, in the field of insulating films, it is being studied to make the K value thereof closer to unity as much as possible by giving the films a porous structure by introducing an air layer into the film. In the case of such a structure, however, the film is generally fragile. In the course of CMP processing of the film, therefore, the insulating film can be broken and peeling of the metallic film can take place due to insufficient adhesiveness. Thus, it is necessary to carry out the polishing while minimizing the stress applied to the substrate. The present invention makes it possible to carry out the polishing under a low load and thus can satisfy this requirement of the process.

Hereinbelow, a method for producing a semiconductor substrate will be explained concretely.

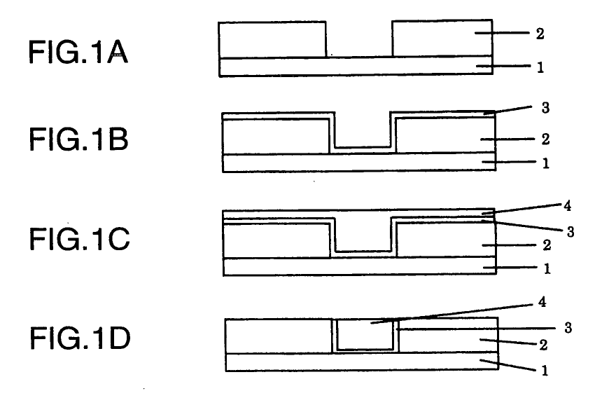

At first, as shown in FIG. 1A, an insulating film 2 is formed on a semiconductor substrate 1, such as a silicon substrate or the like, and thereafter, trenches for metallic wiring or openings for contact wirings are formed on the insulating film 2 by photolithography or etching. Subsequently, as shown in FIG. 1B, a barrier metal layer 3 constituted of titanium nitride (TiN), tantalum nitride (TaN) or the like is formed on the trenches or opening part on the insulating film 2 by sputtering, CVD or the like. Subsequently, as shown in FIG. 1C, metallic film 4 for wiring is embedded so that the thickness thereof becomes higher than the height of the trenches or openings formed on the insulating film 2. Subsequently, as shown in FIG. 1D, the superfluous metallic film present in the areas other than the trenches or opening parts are removed by a polishing treatment with the polishing fluid of the present invention. Further, the series of steps mentioned above are repeated as necessary, whereby a semiconductor substrate having a multilevel interconnection structure as an electronic part can be obtained. In the production of the above-mentioned semiconductor substrate, the polishing of the metallic film on the semiconductor substrate can be carried out by applying the above-mentioned polishing fluid for metallic films and carring out the method for producing a semiconductor substrate.

Hereinbelow, the present invention will be explained by reference to examples. The present invention is by no means limited by these examples.

Characteristic properties and polishing performance of a polishing fluid were evaluated according to the methods mentioned below.

<Measurement of Particle Diameter>

(1) Fine particles (smaller than 5 μm): Measured by a wet type particle size analyzer (MICROTRAC UPA-9230, manufactured by Nikkisou-sha).

(2) Coarse particles (5 μm or larger): Measured by a wet type particle size analyzer (LA-700, manufactured by Horiba Seisakusho).

In the descriptions given hereafter, the term “average particle diameter” means a number-average particle diameter.

<Evaluation of Surface Scratch>

A silicon wafer which has been polished in the aforementioned measurement of polishing rate is washed and dried, and then the surface of the semiconductor wafer was spotlighted in a dark room, and the presence or absence of one of more scratches is judged by visual observation.

<Evaluation of Dishing>

By the same method as in the above-mentioned measurement of polishing rate, a 4″ pattern wafer cut out from a 8″ wafer (SKW6-2 specification: oxide film 0.8 μm, TaN 24 nm, Cu 1.5 μm) was polished under a prescribed load, and a line and space part having intervals of 50 μm is measured with a desk-top type small-sized probe microscope: Nanopics (manufactured by Seiko Insturuments Co.), to determine the quantity of dishing on the Cu surface embedded in the space parts. In this evaluation of dishing, the period of time required for completely polishing a prescribed film thickness is calculated from the measured polishing rate, and a ten percent longer period of time based on this value is used as the polishing time (10% overpolishing).

<Measurement of Pad Surface Roughness (Ra)>

Roughness of pad surface is measured by the use of the desk-top type small-sized probe microscope (Nanopics) used in the above-mentioned dishing measurement.

<Polishing Conditions>

The conditions described below are adopted as standard conditions of polishing, unless otherwise stated.
Polishing apparatus: Polishing Apparatus MA-300D, manufactured by Musashino Denshi Co.
Load: 5 KPa
Relative velocity between substrate and polishing stool: 50 m/min.
Amount of polishing fluid supplied: 50 ml/min.
Polishing pad: After fixing IC-1400 (made of foamed polyurethane) on a polishing stool and dipping it in water, a treatment is carried out under a load of 20 KPa for one hour by the use of a 4″ bare silicon wafer, to remove the defects present on the initial surface of the pad, such as burrs and the like, after which the substrate is subjected to polishing. The polishing rate (PR₁₀) used for specifying the polishing fluid indicates the value under a load of 10 KPa.

The examples shown below are examples of the cases of combining polyoxo acid with a nonionic surfactant.

### EXAMPLE 1

As a polyoxo acid, 12 g of phosphovanadomolybdic acid (PVMo, trade name PVM-1-11, manufactured by Nippon Muki Kagku Kogyo-sha), was dissolved in 68 g of water. While stirring it with a homogenizer, thereto was added a non-ionic surfactant prepared by mixing 18 g of polyoxyethylene lauryl ether (SF-1, trade name BLAUNON EL-1503P, HLB=8.3, manufactured by Aoki Yushi Kogyo-sha) with 102 g of water, to obtain a polishing fluid for metallic film. Characteristic properties of the polishing fluid thus obtained (ER: etching rate, PR₁₀: polishing rate under a load of 10 KPa, contrast: PR₁₀/ER, average particle diameter) and the results of evaluation of performance under prescribed conditions (PR: polishing rate, quantity of dishing, scratch) are shown in Table 1.

### EXAMPLE 2

A polishing fluid for metallic film was prepared in the same manner as in Example 1, except that as the non-ionic surfactant, polyoxyethylene oleyl ether SF-2 (trade name BLAUNON EN-905, HLB=8.9, manufactured by Aoki Yushi Kogyo-sha) was used in place of the SF-1. Results of the evaluation are shown in Table 1.

### EXAMPLE 3

A polishing fluid for metallic film containing an anti-corrosive agent was prepared by adding benzotriazole (BTA) to the polishing fluid composition obtained in Example 2 so that the concentration of BTA was 50 ppm. Results of the evaluation are shown in Table 1.

### EXAMPLE 4

A polishing fluid for metallic film was prepared in the same manner as in Example 1, except that silicomolybdenic acid SiMo (trade name SM, manufactured by Nippon Muki Kagaku Kogyo-sha) was used as the polyoxo acid. Results of the evaluation are shown in Table 1.

### EXAMPLE 5

A polishing fluid for metallic film was prepared in the same manner as in Example 1, except that, as the non-ionic surfactant, a mixture of 12 g of polyoxyethylene lauryl ether SF-3 (trade name BLAUNON EL-1502.2, HLB=6.3, manufactured by Aoki Yushi Kagaku Kogyo-sha) and 108 g of pure water was used in place of SF-1. Results of the evaluation are shown in Table 1.

### EXAMPLE 6

A polishing fluid for metallic film was prepared by dissolving 6 g of PVMo as a polyoxo acid in 74 g of water, adding thereto a mixture of 6 g of SF-1 as a non-ionic surfactant and 54 g of pure water while stirring the whole mixture with a homogenizer, and thereafter adding thereto a mixture of 6 g of non-ionic surfactant SF-3 and 54 g of water. Results of the evaluation are shown in Table 1.

### EXAMPLE 7

A polishing fluid for metallic film was prepared by dissolving 12 g of PVMo as a polyoxo acid in 68 g of water, adding thereto a mixture of 8 g of polyoxyethylene cetyl ether SF-4 (trade name BLAUNON CH-305, HLB=9.4, manufactured by Aoki Yushi Kogyo-sha) as a non-ionic surfactant and 52 g of pure water while stirring the whole mixture with a homogenizer, and then adding thereto a mixture of 3 g of polyoxyethylene 2-ethylhexyl ether SF-5 (trade name BLAUNON EH-2, HLB=8.1, manufactured by Aoki Yushi Kogyo-sha) as a non-ionic surfactant and 57 g of pure water. Results of the evaluation are shown in Table 1.

### EXAMPLE 8

A polishing fluid for metallic film was prepared in the same manner as in Example 7, except that, as the non-ionic surfactant, polyoxyethylene stearyl ether SF-6 (trade name BLAUNON SR-705, HLB=9.2, manufactured by Aoko Yushi Kogyo-sha) was used in place of SF-4. Results of the evaluation are shown in Table 1.

### EXAMPLE 9

A polishing fluid for metallic film was prepared by dissolving 12 g of PVMo as a polyoxo acid in 68 g of water, adding thereto a mixture of 6 g of the above-mentioned non-ionic surfactant SF-4 and 54 g of pure water while stirring the mixture by means of a homogenizer, and subsequently adding thereto a mixture of 2 g of polyoxyethylene synthetic alcohol ether SF-7 (trade name BLAUNON OX-20, HLB=5.7, manufactured by Aoki Yushi Kogyo-sha) as a non-ionic surfactant and 58 g of water. Results of the evaluation are shown in Table 1.

### EXAMPLE 10

A polishing fluid containing an anti-corrosive agent was prepared by adding benzotriazole (BTA) to the polishing fluid obtained in Example 9, so that the concentration of BTA became 50 ppm. Results of the evaluation of this polishing fluid are shown in Table 1.

### EXAMPLE 11

A polishing fluid for metallic film was prepared by dissolving 6 g of PVMo as a polyoxy acid in 74 g of water, and adding thereto a mixture of 24 g of SF-2 as a non-ionic surfactant and 96 g of water while stirring the mixture by means of a homogenizer. Results of the evaluation are shown in Table 1. The polishing fluid obtained herein was somewhat high in viscosity.

### EXAMPLE 12

The polishing performance was evaluated in the same manner as in Example 1, except that the load of polishing was increased to 25 KPa. The results are shown in Table 1.

### EXAMPLE 13

The polishing performance was evaluated in the same manner as in Example 1, except that the relative velocity between substrate and polishing stool was lowered to 19 m/min. The results are shown in Table 1.

### EXAMPLE 14

A polishing experiment was carried out by the use of the polishing fluid obtained in Example 1, on a substrate prepared by forming a Cu film having a thickness of about 0.8 μm on a methylsilsesquioxane type insulating film having a porous structure and having a dielectric constant of 2.1. The polishing was carried out under a low load of 5 KPa in the same manner as in Example 1. Neither peeling nor crack of the Cu film was observed at all, until the completion of the polishing.

Each of the polishing fluids containing fine particles obtained in the above-mentioned examples was dropped onto a grid equipped with a carbon supporting film and subjected to air drying to obtain a microscopic test piece. The test pieces thus obtained were observed under a transmission type electron microscope (HITACHI HF-2000, accelerating voltage 200 KV) to investigate their particle structure. As a result, the existence of particles in the form where the polyoxo acid was incorporated into the non-ionic surfactant was observed. Although the particle size varied depending on the polishing composition, it ranged from about 20 nm to 50 nm, and some particles showed a structure of a coagulated product thereof.

### COMPARATIVE EXAMPLE 1

A polishing fluid for metallic film was prepared in the same manner as in Example 1, except that, in place of the non-ionic surfactant, the same amount of sodium docecylbenzenesulfonate SF-8 which is an anionic surfactant was used. The polishing fluid obtained herein was a uniform solution so that particle diameter could not be measured. Results of the evaluation are shown in Table 1.

### COMPARATIVE EXAMPLE 2

A polishing fluid for metallic film was prepared in the same manner as in Example 1, except that, in place of the non-ionic surfactant, the same amount of lauryl trimethylammonium chloride SF-9 which is a cationic surfactant was used. Results of the evaluation are shown in Table 1.

### COMPARATIVE EXAMPLE 3

As a polyoxo acid, 12 g of phosphovanadomolybdic acid PVMo was dissolved in 188 g of water, and the resulting solution was used as it was as a polishing fluid for metallic film. Since the polishing fluid obtained herein contained no surfactant and the like at all, it was a uniform solution, so that the particle diameter could not be measured. Results of the evaluation are shown in Table 1.

### COMPARATIVE EXAMPLE 4

As a polyoxo acid salt, 12 g of ammonium phosphomolybdate NPMo ((NH₄)₃[PMo₁₂O₄₀], manufactured by Nippon Muki Kagaku-sha) was thoroughly pulverized, added to 88 g of water and dispersed by means of a homogenizer. Subsequently, 100 g of colloidal alumina (average particle diameter 130 nm, manufactured by Shokubai Kasei-sha) was added so that the concentration of the abrasive grain in the composition was 6%, and the whole mixture was dispersed by means of a homogenizer. Thus, a polishing fluid containing alumina particles as abrasive grains was obtained. Results of evaluation are shown in Table 1.

### COMPARATIVE EXAMPLE 5

A polishing fluid for metallic film was prepared by dissolving 6 g of citric acid in 62 g of water, adding thereto a solution of 0.4 g of BTA in 3 g of ethanol, further adding thereto 100 g of colloidal alumina (the same as the above) so that concentration of the abrasive grains in the polishing fluid was 6%, and finally adding 28 g of aqueous hydrogen peroxide (extra pure grade reagent, 30% aqueous solution). Results of the evaluation are shown in Table 1.

### COMPARATIVE EXAMPLE 6

A polishing fluid for metallic film was prepared by dissolving 5 g of phosphovanadomolybdic acid (PVMo) in 195 g of water, adding thereto KOH so that the pH was 3.5 while stirring the mixture by means of a homogenizer, and further adding colloidal alumina (the same as the above) so that the concentration of the abrasive grains in the polishing fluid was 3%. Results of the evaluation are shown in Table 1.

### COMPARATIVE EXAMPLE 7

The polishing performance was evaluated in the same manner as in Comparative Example 6, except that the load of polishing was 30 KPa.

### COMPARATIVE EXAMPLE 8

A substrate was formed in the same manner as in Example 13 by forming a Cu film having a thickness of about 0.8 μm on a methylsilsesquioxane type insulating film having a porous structure and having a dielectric constant of 2.1. This substrate was subjected to a polishing experiment under the same conditions as in Comparative Example 7. As a result, peeling of the Cu film occurred in the course of polishing.

From the above-mentioned results of the Examples and Comparative Examples, it is apparent that the polishing fluids of the present invention comprising a combination of polyoxo acid and a non-ionic surfactant exhibit a high polishing rate of 400 nm/min. or more on copper film under a low load of 5 KPa under the condition of the relative velocity between substrate and polishing stool of 50 m/min., and that more advantageously prevent defects, such as scratching and the like, under a lower load. Further, owing to such an advantageous characteristic feature, they can be used to polish substrates using an insulating film made of a fragile porous type low dielectric constant material, without any problem. Although there is a tendency that a decrease in the relative velocity between the substrate and the polishing stool causes a decrease in polishing rate, the polishing rate is still maintained at a high value of about 300 nm/min.

It is apparent that the polishing fluid of the present invention exhibits the characteristic effect only when combined with a non-ionic surfactant, and it cannot exhibit a sufficient effect when combined with an anionic or cationic surfactant. When a polishing fluid comprising only heteropoly acid is used, the desired performance cannot be exhibited due to the excessively high etching property. On the other hand, when it is attempted to suppress the etching property of heteropoly acid by converting the heteropoly acid into an ammonium or potassium salt, a decrease in polishing performance occurs simultaneously, and sufficient polishing performance cannot be exhibited at a low load of 5 KPa even if abrasive grains are added.

The examples presented below are examples of polishing fluid in which polyoxo acid and a water-soluble polymer are combined.

### EXAMPLE 15

A polishing fluid for metallic film was prepared by dissolving 6 g of PVMo as a polyoxo acid in 154 g of water, and adding thereto, while stirring the whole mixture with a homogenizer, an aqueous solution prepared by dissolving 6 g of polyvinyl pyrrolidone K30: PVP (average molecular weight 40,000, manufactured by Wako Junyaku Kogyo K. K.) as a water-soluble polymer in 34 g of water. Results of the evaluation are shown in Table 2.

### EXAMPLE 16

A polishing fluid for metallic film was prepared by dissolving 6 g of PVMo as a polyoxo acid in 114 g of water, and adding thereto, while stirring the whole mixture with a homogenizer, an aqueous solution prepared by dissolving 12 g of PVP as a water-soluble polymer in 68 g of pure water. Results of the evaluation are shown in Table 2.

### EXAMPLE 17

A polishing fluid for metallic film was prepared by dissolving 6 g of PVMo as a polyoxo acid in 62 g of water, and adding thereto, while stirring the whole mixture with a homogenizer, an aqueous solution prepared by dissolving 40 g of polyethylene glycol 4000: PEG-1 as a water-soluble polymer (average molecular weight 3,000, manufactured by Wako Junyaku Kogyo-sha) in 92 g of pure water. The composition thus obtained formed a uniform solution, so that the particle diameter could not be measured. Results of the evaluation are shown in Table 2.

### EXAMPLE 18

A polishing fluid for metallic film was prepared by dissolving 6 g of PVMo as a polyoxo acid in 94 g of water, and adding thereto, while stirring the whole mixture with a homogenizer, an aqueous solution prepared by dissolving 30 g of polyethylene glycol 20000: PEG-2 as a water-soluble polymer (average molecular weight 20,000, manufactured by Wako Junyaku Kogyo-sha) in 70 g of water. The composition thus obtained formed a uniform solution, so that the particle diameter could not be measured. Results of the evaluation are shown in Table 2.

### EXAMPLE 19

A polishing fluid for metallic film was prepared by dissolving 9 g of PVMo as a polyoxo acid in 123 g of water, adding thereto, while stirring the mixture with a homogenizer, an aqueous solution prepared by dissolving 15 g of PEG-1 as a water-soluble polymer in 35 g of water, and subsequently adding thereto 18 g of the above-mentioned SF-1 as a non-ionic surfactant. Results of the evaluation are shown in Table 2.

### EXAMPLE 20

A polishing fluid for metallic film containing an anti-corrosive agent was obtained by adding BTA to the polishing composition obtained in Example 18, so that the concentration of BTA was 50 ppm. Results of the evaluation are shown in Table 2.

### EXAMPLE 21

A polishing fluid for metallic film was prepared in the same manner as in Example 19, except that, as the non-ionic surfactant, SF-2 was used in place of the SF-1. Results of the evaluation are shown in Table 2.

### EXAMPLE 22

A polishing fluid for metal was prepared by dissolving 6 g of PVMo as a polyoxo acid in 168 g of water, adding thereto, while stirring the mixture with a homogenizer, an aqueous solution prepared by dissolving 6 g of PEG-1 as a water-soluble polymer in 14 g of pure water, and subsequently adding thereto 6 g of SF-3. Results of the evaluation are shown in Table 2.

### EXAMPLE 23

A polishing fluid for metallic film was prepared by dissolving 9 g of PVMo as a polyoxo acid in 116 g of water and 6 g of ethanol, adding thereto, while stirring the mixture with a homogenizer, an aqueous solution prepared by dissolving 9 g of PVP as a water-soluble polymer in 51 g of pure water, and subsequently adding thereto 9 g of non-ionic surfactant SF-1. Results of the evaluation are shown in Table 2.

### EXAMPLE 24

A polishing fluid for metallic film was prepared by dissolving 12 g of PVMo as a polyoxo acid in 178 g of water, then adding thereto 6 g of a non-ionic surfactant SF-4 while stirring the mixture by means of a homogenizer, and then adding thereto an aqueous solution prepared by dissolving 0.4 g of hydroxypropyl cellulose HPC (150-400 mPa.s, manufactured by Wako Junyaku Kogyo K. K.) as a water-soluble polymer in 3.6 g of pure water. Results of the evaluation are shown in Table 2.

### EXAMPLE 25

Using each of the polishing fluids obtained in Examples 17 and 22, a polishing experiment on a substrate prepared by forming a Cu film having a thickness of about 0.8 μm on a methylsilsesquioxane type insulating film having a porous structure and having a dilelectric constant of 2.1 was carried out. The polishing was carried out under a low load of 5 KPa in the same manner as above. As a result, neither peeling nor crack of the Cu film was observed at all, until the completion of the polishing.

### COMPARATIVE EXAMPLE 9

In 60 g of water were dissolved 6 g of citric acid and 6 g of PVP as a water-soluble polymer. Thereto was added 100 g of colloidal alumina (the same as above) so that the concentration of the abrasive grain in the composition was 6%, and thereto was further added 28 g of aqueous hydrogen peroxide (extra pure grade, 30% aqueous solution). Thus, a polishing fluid for metallic film was obtained. Results of the evaluation are shown in Table 2.

From the results shown in Table 2, it is apparent that, in the combination of polyoxo acid and a water-soluble polymer also, it is possible to exhibit a high polishing rate while suppressing the etching property at a low level, similarly to the aforementioned case of combination with a non-ionic surfactant. It has also been found that a case of combining polyoxo acid with both water-soluble polymer and non-ionic surfactant tends to exhibit a relatively higher polishing rate. On the other hand, even if an etching agent other than polyoxo acid is combined with a water-soluble polymer, the etching property cannot be suppressed, and polishing treatments using such a polishing fluid show a great extent of dishing and have a problem in the polishing performance.

The examples presented below are for the purpose of evaluating the influence of the dressing operation of pads on the polishing performance.

### EXAMPLE 26

In order to assess how the absence of dressing (dressing for refreshing the pad) influences polishing performance, the polishing fluid used in Example 9 was introduced into a flanged polishing stool in an amount sufficient to immerse a wafer to be polished, and a 4″ dummy wafer was polished for one hour on the pad. Subsequently, the pad was only lightly washed with water by the use of a nylon brush, without carrying out any dressing treatment of the pad surface. Then, the polishing performance was evaluated in the same manner as in Example 9, except that the pad obtained herein was used. Surface roughness (Ra) of this pad was 456 nm. The results are shown in Table 3.

### EXAMPLE 27

Polishing performance was evaluated in the same manner as in Example 9, except that, as the pad, a non-foamed polishing pad (Ra=120 nm) called MF Plastic plate with grooves (manufactured by Musashino Denshi-sha) was used. The results are shown in Table 3.

### COMPARATIVE EXAMPLE 10

Prior to polishing, a pad was subjected to dressing for one hour under a load of 3 KPa by the use of a #100 conditioner with embedded diamond. Polishing performance was evaluated in the same manner as in Comparative Example 5, except that the pad obtained above was used and the polishing load was altered to 30 KPa. The results are shown in Table 3.

### COMPARATIVE EXAMPLE 11

The same pad as used in Comparative Example 10 which had undergone dressing was subjected to the same treatment as in Example 26 to obtain a non-refreshed pad. Using this pad, polishing performance was evaluated in the same manner as in Comparative Example 5, provided that the polishing load was 30 KPa.

From the results shown in Table 3, it is apparent that the present invention gives a polishing performance comparable to that in the initial case, even if the dressing, which is usually frequently carried out in the course of polishing for the purpose of refreshing the pad, is not carried out. Further, it is also apparent that when a pad having a very flat surface is used, an improved dishing property can be obtained without any extreme decrease in polishing rate. Contrariwise, in the conventional polishing fluids containing alumina abrasive grains, the dressing can improve the polishing rate, but the polishing rate decreases if the dressing for refreshing is not carried out in the course of polishing.

### EXAMPLE 28

A copper film and a TaN film were polished under a load of 5 KPa by the use of the polishing fluid prepared according to Example 9 and a polishing pad prepared by pre-treating MH C15A (a pad prepared by incorporating cerium oxide into a urethane resin, manufactured by RODEL NITTA Co.) by the use of a #4000 dresser for 10 minutes. As a result, the polishing rate was 580 nm/min. and 80 nm/min., respectively. When a thermally oxidized film was polished under the same conditions as above, the polishing rate was about 1 nm/min., demonstrating that polishing hardly progressed. At this time, no scratch was found at all on the polished surface. Subsequently, using this polishing fluid, a patterned wafer was polished for 3 minutes according to the dishing evaluation method, and the quantity of dishing was measured and found to be about 70 nm. At this time, it was found that the TaN film in the areas other than the trench part could not be detected with a metal film thickness meter, demonstrating its disappearance.

### COMPARATIVE EXAMPLE 12

A polishing fluid consisting only of polyoxo acid was prepared by dissolving 2 g of PVMo as a polyoxo acid in 198 g of water. Evaluation was carried out in the same manner as in Example 28, except that this polishing fluid was used. Thus, when a copper film, a TaN film and a thermally oxidized film were polished, the polishing rate was 520 nm/min., 30 nm/min. and 1 nm or less, respectively. The etching rate of copper film was as large as 110 nm/min. Subsequently, using this polishing fluid, a pattern wafer was polished to evaluate the dishing. When the polishing was continued for 3 minutes and thereafter the quantity of dishing was measured, a cavity of about 400 nm on the average, was formed, and the trench part was in local etched form.

From the results mentioned above, it is apparent that, if polishing is carried out by the use of the polishing fluid for metallic film according to the present invention and an inorganic filler-containing polishing pad, polishing of copper film can be carried out at a very high polishing rate of 580 nm/min. even under a extremely low load of 5 KPa, and tantalum compounds which have hitherto been difficult to polish can be polished at a high polishing rate of 80 nm. Further, as in the case of copper and TaN which are different from each other in polishing rate, both of the materials can be polished in one step while maintaining low dishing. This is because the polishing fluid of the present invention is characterized by being able to selectively polish the metallic films only at the site where the pad contacts the metallic films under the force greater than a certain level. Even when polishing of copper progresses at a higher rate than on the TaN film, the load is eliminated at the sites where polishing has progressed excessively, and the polishing at these sites stops at this stage. On the other hand, according to the polishing method of the present invention, silicon dioxide film is hardly polished, so that the polishing can be carried out continuously on a copper film and a barrier film to complete the polishing on the oxide film. Accordingly, the present invention can greatly contribute to the simplification of the semiconductor manufacturing process which involves a complicated CMP process.

TABLE 1

| | Properties of | | | | | | | | Polishing | | |
|---|---|---|---|---|---|---|---|---|---|---|---|
| | polishing fluid | | | | Conditions of polishing | | | | performance | | |
| | ER (nm/min.) | PR₁₀(nm/min.) | Contrast PR/ER | Average particle diameter (nm) | Load (KPa) | Relative velocity (m/min.) | 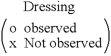 | Ra (nm) | PR (nm/min.) | Quality of dishing (nm) | 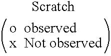 |
| Ex. 1 | 6 | 600 | 100 | 30 | 5 | 50 | x | 482 | 570 | 69 | x |
| Ex. 2 | 7 | 600 | 86 | 40 | 5 | 50 | x | 482 | 580 | 75 | x |
| Ex. 3 | 0.9 | 570 | 630 | 40 | 5 | 50 | x | 482 | 550 | 48 | x |
| Ex. 4 | 5 | 580 | 120 | 30 | 5 | 50 | x | 482 | 560 | 73 | x |
| Ex. 5 | 0.9 | 460 | 510 | 140 | 5 | 50 | x | 482 | 450 | 50 | x |
| Ex. 6 | 4 | 530 | 130 | 100 | 5 | 50 | x | 482 | 480 | 70 | x |
| Ex. 7 | 6 | 560 | 93 | 370 | 5 | 50 | x | 482 | 540 | 68 | x |
| Ex. 8 | 7 | 560 | 80 | 360 | 5 | 50 | x | 482 | 530 | 66 | x |
| Ex. 9 | 5 | 570 | 110 | 160 | 5 | 50 | x | 482 | 550 | 64 | x |
| Ex. 10 | 0.8 | 530 | 660 | 160 | 5 | 50 | x | 482 | 500 | 41 | x |
| Ex. 11 | 3 | 450 | 150 | 7 | 5 | 50 | x | 482 | 420 | 55 | x |
| Ex. 12 | 6 | 600 | 100 | 30 | 25 | 50 | x | 482 | 620 | 75 | Slightly ∘ |
| Ex. 13 | 6 | 600 | 100 | 30 | 5 | 19 | x | 482 | 280 | 96 | x |
| Comp. Ex. 1 | 530 | 660 | 1.2 | — | 5 | 50 | x | 482 | 570 | >1200 | x |
| Comp. Ex. 2 | 23 | 540 | 23 | 10000 | 5 | 50 | x | 482 | 480 | 266 | ∘ |
| Comp. Ex. 3 | 560 | 680 | 1.2 | — | 5 | 50 | x | 482 | 580 | >1200 | x |
| Comp. Ex. 4 | 4 | 112 | 28 | 160 | 5 | 50 | x | 482 | 50 | 103 | x |
| Comp. Ex. 5 | 1.2 | 60 | 50 | 150 | 5 | 50 | x | 482 | 35 | 55 | ∘ |
| Comp. Ex. 6 | 3 | 110 | 63 | 180 | 5 | 50 | x | 482 | 60 | 73 | ∘ |
| Comp. Ex. 7 | 3 | 110 | 63 | 180 | 30 | 50 | x | 482 | 290 | 98 | ∘ |

TABLE 2

| | Properties of | | | | | | | | Polishing | | |
|---|---|---|---|---|---|---|---|---|---|---|---|
| | polishing fluid | | | | Conditions of polishing | | | | performance | | |
| | ER (nm/min.) | PR₁₀(nm/min.) | Contrast PR/ER | Average particle diameter (nm) | Load (KPa) | Relative velocity (m/min.) | 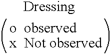 | Ra (nm) | PR (nm/min.) | Quality of dishing (nm) | 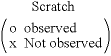 |
| Ex. 15 | 2 | 440 | 220 | 700 | 5 | 50 | x | 482 | 420 | 58 | x |
| Ex. 16 | 0.7 | 420 | 600 | 10 | 5 | 50 | x | 482 | 410 | 49 | x |
| Ex. 17 | 4 | 490 | 120 | — | 5 | 50 | x | 482 | 470 | 60 | x |
| Ex. 18 | 3 | 460 | 150 | — | 5 | 50 | x | 482 | 440 | 59 | x |
| Ex. 19 | 6 | 550 | 92 | 70 | 5 | 50 | x | 482 | 520 | 61 | x |
| Ex. 20 | 0.9 | 500 | 560 | 70 | 5 | 50 | x | 482 | 490 | 65 | x |
| Ex. 21 | 8 | 590 | 74 | 150 | 5 | 50 | x | 482 | 570 | 66 | x |
| Ex. 22 | 1 | 590 | 590 | 120 | 5 | 50 | x | 482 | 580 | 71 | x |
| Ex. 23 | 0.7 | 430 | 610 | 300 | 5 | 50 | x | 482 | 420 | 52 | x |
| Ex. 24 | 9 | 650 | 72 | 320 | 5 | 50 | x | 482 | 630 | 83 | x |
| Comp. Ex. 9 | 480 | 630 | 1.3 | 150 | 5 | 50 | x | 482 | 600 | >1200 | x |

TABLE 3

| | Properties of | | | | | | | | Polishing | | |
|---|---|---|---|---|---|---|---|---|---|---|---|
| | polishing fluid | | | | Conditions of polishing | | | | performance | | |
| | ER (nm/min.) | PR₁₀(nm/min.) | Contrast PR/ER | Average particle diameter (nm) | Load (KPa) | Relative velocity (m/min.) | 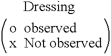 | Ra (nm) | PR (nm/min.) | Quality of dishing (nm) | 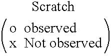 |
| Ex. 26 | 5 | 570 | 110 | 160 | 5 | 50 | x | 456 | 540 | 65 | x |
| Ex. 27 | 5 | 570 | 110 | 160 | 5 | 50 | x | 120 | 530 | 49 | x |
| Comp. Ex. | 1.2 | 60 | 50 | 150 | 30 | 50 | ∘ | 2660 | 530 | 122 | Slightly o |
| 10 | | | | | | | | | | | |
| Comp. Ex. | 1.2 | 60 | 50 | 150 | 30 | 50 | ∘ | 630 | 230 | 74 | o |
| 11 | | | | | | | | | | | |

### INDUSTRIAL APPLICABILITY

If the polishing fluid for metallic films according to the present invention is used, it becomes possible to suppress the etching and dishing and, at the same time, to polish a metallic film, such as copper film and the like, at a high polishing rate even under a low load. Thus, the polishing fluid of the present invention is effectively used particularly for polishing a metallic film present on a fragile substrate, such as a porous type low dielectric constant insulating film substrate and the like. Further, since the present invention makes it unnecessary to carry out the troublesome step of dressing of the pad, a great simplification of the process becomes possible. As above, the present invention relates to a material having very useful performances in the polishing of metallic films formed on a semiconductor substrate, so that it has a very high industrial applicability.

1. A polishing fluid for metallic films, the polishing fluid having an etching rate of 10 nm/min. or less, a polishing rate under a load of 10 KPa of 200 nm/min. or more, and a contrast ratio of the polishing rate to the etching rate of 20 or more.

2. A polishing fluid for metallic films, comprising a polyoxo acid and/or a salt thereof, a water-soluble polymer and/or a non-ionic surfactant, and water.

3. A polishing fluid for metallic films according to claim 2, comprising a particulate composite material consisting of a polyoxo acid and/or a salt thereof and a non-ionic surfactant.

4. A polishing fluid for metallic films according to anyone of claims 2 to 3, wherein abrasive grains are substantially not contained.

5. A polishing fluid for metallic films according to claim 2 or 3, wherein said polyoxo acid and/or a salt thereof is a heteropoly acid and/or a salt thereof.

6. A polishing fluid for metallic films according to claim 2 or 3, wherein the HLB of the non-ionic surfactant is 5 to 12.

7. A polishing fluid for metallic films according to claim 2 or 3, wherein the non ionic surfactant is a polyoxyethylene ether of a saturated type higher alcohol having 8 to 24 carbon atoms.

8. A polishing fluid for metallic films according to claim 2 or 3, wherein the non ionic surfactant is a combination of two or more kinds of non-ionic surfactants with different HLBs.

9. A method for producing a semiconductor substrate comprising a step of polishing a metallic film formed on the semiconductor substrate, wherein the polishing is carried out with a polishing fluid for metallic films according to any one of claims 1 to 3 under a load of 15 KPa or less.

10. A method for producing a semiconductor substrate comprising a step of polishing a metallic film formed on the semiconductor substrate with a polishing stool, wherein the polishing is carried out with a polishing fluid for metallic films according to any one of claims 1 to 3 at a relative velocity between the semiconductor substrate and the polishing stool of 40 m/min. or more.

11. A method according to claim 9, wherein, in the step of polishing, the polishing is carried out with a polishing pad not subjected to a dressing treatment.

12. A method according to claim 9, wherein, in the step of polishing, the polishing is carried out with a polishing pad having an average surface roughness (Ra) of 1,000 nm or less on its surface.

13. A method according to claim 9, wherein, in the step of polishing, the polishing is carried out with a polishing fluid for metallic films according to any one of claims 1 to 3 and by a polishing pad containing an inorganic filler.

14. A method according to claim 9, wherein the relative dielectric constant (K) of the insulating film constituting the semiconductor substrate is 2.5 or less.

15. A polishing fluid for metallic films according to claim 1, wherein abrasive grains are substantially not contained.

16. A method according to claim 10, wherein, in the step of polishing, the polishing is carried out with a polishing pad not subjected to a dressing treatment.

17. A method according to claim 10, wherein, in the step of polishing, the polishing is carried out with a polishing pad having an average surface roughness (Ra) of 1,000 nm or less on its surface.

18. A method according to claim 10, wherein, in the step of polishing, the polishing is carried out with a polishing fluid for metallic films according to any one of claims 1 to 3 and by a polishing pad containing an inorganic filler.

19. A method according to claim 10, wherein the relative dielectric constant (K) of the insulating film constituting the semiconductor substrate is 2.5 or less.
